(19) United States
(12) Patent Application Publication
(10) Pub. No.: US 2007/0200220 A1
(43) Pub. Date: Aug. 30, 2007

(54) FLEXIBLE SUBSTRATE

(75) Inventors: Makoto Murai, Gifu (JP); Ryosuke Usui, Aichi (JP)

Correspondence Address: FISH & RICHARDSON P.C., P.O. BOX 1022, MINNEAPOLIS, MN, 55440-1022, US

(73) Assignee: SANYO ELECTRIC CO., LTD., Osaka (JP)

(21) Appl. No.: 11/678,309

(22) Filed: Feb. 23, 2007

(30) Foreign Application Priority Data
Feb. 24, 2006 (JP) 2006-049344
Jan. 31, 2007 (JP) 2007-021890

(51) Int. Cl. H01L 23/053

(52) U.S. Cl. 257/701

(57) ABSTRACT

A flexible substrate is provided which contains not only flexibility but also rigidity and hear resistance. A flexible substrate includes a first wiring layer, an insulating resin layer, a glass cloth and a second wiring layer. The insulating layer is formed by an insulating material, such as a BT resin, epoxy resin or the like that contains a high elastic modulus, heat resistance and moisture resistance. The film thickness of the insulating resin layer is thinned down to about 60 μm. As a reinforcing material, the glass cloth is embedded in the insulating resin layer. With this structure, the flexible substrate attains flexibility and at the same time in any of the first wiring layer and the second wiring layer, circuit elements can be mounted both on a curved area and a non-curved area of the wiring layers.

### BACKGROUND OF THE INVENTION

1. Field of the Invention

The present invention relates to a flexible substrate known also as a flexible wiring board and, more particularly, to a flexible substrate suited to the mounting of circuit elements thereon.

2. Description of the Related Art

In recent years, as more and more electronic equipment come in smaller sizes and with higher functions, the on-going trend in the circuit devices used in such electronic equipment is toward smaller size, higher density, and greater sophistication such as multiple functions. Also, demand is growing for wiring boards having flexibility, called flexible substrates, so as to wire a large number of circuit devices within a housing of electronic equipment. Use of such flexible substrates increases the freedom of arrangement of circuit devices, thus making it possible to place more circuit devices in a limited space of housing.

So far, because of their flexibility, flexible substrates have been used to connect circuit boards installed in the movable parts of mobile equipment, such as mobile phones, laptop PCs, and mobile DVDs.

Related Art List

(1) Japanese Patent Application Laid-Open No. Hei09-3195.

The materials used for conventional flexible substrates have mostly been insulating resins like polyimide resins, which generally lack in rigidity and heat resistance. Thus, they present the problem of difficulty in using the same wire bonding or soldering as is used with rigid substrates. Also, conventional flexible substrates have been liable to swelling deformation because of their poor heat resistance and moisture resistance, which renders them totally unsuited to multilayered structuring.

On the other hand, the conventional rigid substrates have their problem in that they cannot be deformed like flexible substrates which can be used in the movable parts of mobile equipment. Thus, when a rigid substrate is to be electrically connected to such a movable part, it is necessary to provide the rigid substrate with a connector and make the connection using a cable or a flexible substrate via the connector.

### SUMMARY OF THE INVENTION

The present invention has been made to resolve problems as described above, and a general purpose thereof is to provide a flexible substrate which has not only flexibility but also rigidity and heat resistance.

One embodiment of the present invention relates to a flexible substrate. The flexible substrate comprises: an insulating resin layer which contains a high elastic modulus and heat resistance; glass fibers embedded in the insulating resin layer; and a wiring layer provided on at least one surface of said insulating resin layer, wherein the insulating layer is so thinned as to be flexible.

According to this embodiment, the insulating resin layer itself has a material property of being rigid and hear resistant, and it has flexibility in the form of a substrate and can be freely bent or curved. As a result, such processes as wire bonding and soldering can be used even for a bent part of the a circuit board. Thereby, circuit elements can be mounted on not only a bent portion bur also an unbent portion. Hence, the increased packaging area on the flexible substrate 10 with circuit elements mounted also on the bent areas thereof contributes to higher density and smaller size of circuit devices.

In the above embodiment, the insulating resin layer may further contain moisture resistance. According to this embodiment, a swelling deformation because of water absorption in the insulating layer is suppressed, so that a desirable bonding property with circuit elements can be retained. As a result, reliability can be enhanced as a circuit element mounting substrate or board.

In any of the above embodiments, the insulating resin layer may further contain rigidity. According to this embodiment, the flexible substrate can be suitably used as a circuit board where once the flexible substrate is folded or folded in a bent state inside a mobile phone, for example, it will be used in the fixed state.

Also, in any of the above embodiments, at least part of the glass fibers may be exposed on an end face of the insulating resin layer. This arrangement according to this embodiment provides sufficient strength to peripheral edge parts of the insulating resin layer for mounting circuit elements thereon. Thus, by effectively using the peripheral edge area of a circuit board as circuit element mounting area, the packaging area for circuit elements can be increased. Furthermore, when the circuit elements are mounted on the flexible substrate, heat generated by the circuit elements can be easily radiated from the glass fibers exposed on the end faces of the insulating resin layer, so that the heat radiation from the flexible substrate with the circuit elements mounted thereon improves.

It is to be noted that any arbitrary combinations or rearrangement, as appropriate, of the aforementioned constituting elements and so forth are all effective as and encompassed by the embodiments of the present invention.

Moreover, this summary of the invention does not necessarily describe all necessary features so that the invention may also be sub-combination of these described features.

### BRIEF DESCRIPTION OF THE DRAWINGS

Embodiments will now be described by way of examples only, with reference to the accompanying drawings which are meant to be exemplary, not limiting and wherein like elements are numbered alike in several Figures in which:

FIG. 1 is a sectional view showing a structure of a flexible substrate according to an embodiment of the present invention;

FIG. 2 is a photo showing a state of circuit elements mounted on a flexible substrate which has been actually produced;

FIG. 3 is a photo showing a state of circuit elements mounted on a flexible substrate which has been actually produced;

FIG. 4 is a sectional view showing a case where a flexible substrate is used as a circuit board for a mobile phone;

FIG. 5 is a sectional view showing another example where a flexible substrate is used as a circuit board for a mobile phone;

FIG. 6 is a sectional view showing still another example where a flexible substrate is used as a circuit board for a mobile phone; and

FIG. 7 is a sectional view showing still another where a flexible substrate is used as a circuit board for a mobile phone.

### DETAILED DESCRIPTION OF THE INVENTION

The invention will now be described by reference to the preferred embodiments. This does not intend to limit the scope of the present invention, but to exemplify the invention.

The present embodiments will now be described with reference to drawings.

Hereinbelow, the embodiments will be described with reference to the accompanying drawings.

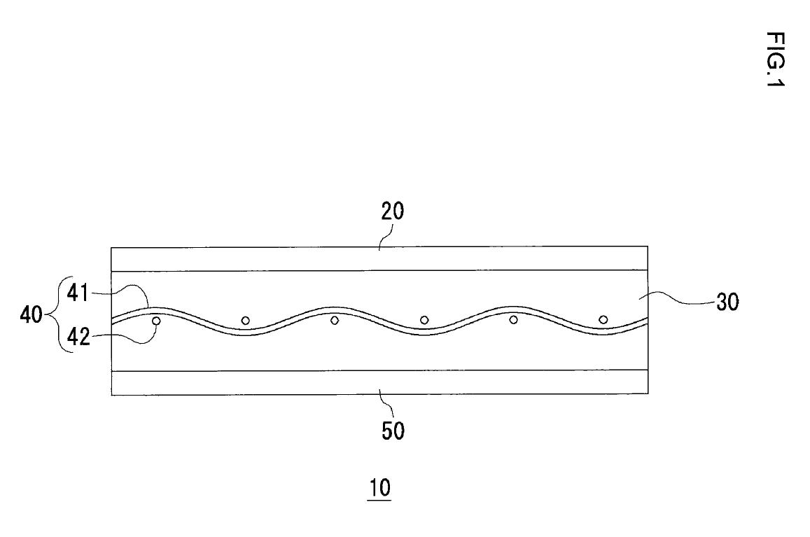

FIG. 1 is a sectional view showing a structure of a flexible substrate 10 according to an embodiment of the present invention. The flexible substrate 10 includes a first wiring layer 20, an insulating resin layer 30, a glass cloth 40, and a second wiring layer 50.

The first wiring layer 20 and the second wiring layer 50, which are made of a metal such as copper, have their respective wiring patterns. The first wiring layer 20 and the second wiring layer 50 may be produced, for instance, by first pressure-bonding copper foil on the insulating resin layer 30, then forming a resist according to a desired wiring pattern on the copper foil by photolithography, and finally selectively etching the copper foil using the resist as a mask.

The insulating resin layer 30 is formed of an insulating material which has a high elastic modulus, high heat resistance and high moisture resistance. Such insulating material may include BT resins and epoxy resins. The thickness of the insulating resin layer 30 is such that it is a thin film having flexibility. For example, a BT resin having a tensile strength of 294 MPa, an elastic modulus of 23.52 GPa and a coefficient of thermal expansion of 15 ppm/K may be used as the insulating resin layer 30, and flexibility may be given to the insulating resin layer 30 by thinning it to a film thickness of about 60 μm. Note that a conventional flexible substrate using polyimide (e.g., Espanex M series manufactured by Nippon Steel Chemical Co., Ltd.) has a tensile strength of 330 MPa, an elastic modulus of 4.3 GPa and a coefficient of thermal expansion of 22 ppm/K, which indicates that the flexible substrate 10 according to the present embodiment displays superior rigidity and heat resistance.

The glass cloth 40 is embedded in the insulating resin layer 30. The glass cloth 40 helps the insulating resin layer 30 retain its strength, so that the insulating resin layer 30 in a thin film may not suffer cracking or other damage when it is bent. The glass cloth 40 contains glass fibers 41, which extend in a direction (horizontal direction on sheet surface of FIG. 1) along the surface direction of the insulating resin layer 30, and glass fibers 42, which extend in a direction intersecting the glass fibers 41 (vertical direction on sheet surface of FIG. 1) and is interwoven with the glass fibers 41. The glass cloth 40 formed in a single layer made up of glass fibers 41 and glass fibers 42 ensures the retention of its strength without impairing the flexibility of the insulating resin layer 30. The structure comprised of the insulating resin layer 30 and the glass cloth 40 can be produced by first impregnating a molten insulating resin layer 30 in a glass cloth 40 and then curing the insulating resin layer 30.

Thus, a flexible substrate 10, which exhibits not only flexibility and pliability but also heat resistance and moisture resistance, is realized by forming the insulating resin layer 30 in a thin film while using a rigid, heat-resistant and moisture-resistant insulating material therefor. Accordingly, such processes as wire bonding and soldering can be used even for the bent parts of the flexible substrate 10. In other words, circuit elements can be mounted on both the first wiring layer 20 and the second wiring layer 50 whether they are bent or not. Hence, the increased packaging area on the flexible substrate 10 with circuit elements mounted also on the bent areas thereof contributes to higher density and smaller size of circuit devices.

The conventional flexible substrate has been in need of a connection terminal by which the wiring thereof is electrically connected to the wiring of a rigid substrate. In contrast to this, the flexible substrate according to the present embodiment is subject to fewer limitations on where to mount the circuit elements, and the unbent part thereof can perform the function of a rigid substrate. Therefore, it can realize a circuit board with movable parts without resorting to the use of a connection terminal which has been necessary with conventional flexible substrates. The flexible substrate according to the present embodiment therefore reduces the number of parts required by a circuit board, simplifies the manufacturing processes and thus reduces the manufacturing cost. Moreover, the absence of a connection terminal on the flexible substrate results in a simplified structure as well as a reduced likelihood of faulty connection.

In the present embodiment, it is preferable that the glass cloth 40 is exposed on the end faces of the insulating resin layer 30. This arrangement provides sufficient strength to the peripheral edge part of the insulating resin layer 30 for mounting circuit elements thereon. Thus, by effectively using the peripheral edge area of the flexible substrate 10 as circuit element mounting area, the packaging area for the circuit elements can be increased. Furthermore, when circuit elements are mounted on a flexible substrate, heat generated by the circuit elements can be easily radiated from the glass fibers exposed on the end faces of the insulating resin layer, so that the heat radiation from the flexible substrate with the circuit elements mounted thereon improves.

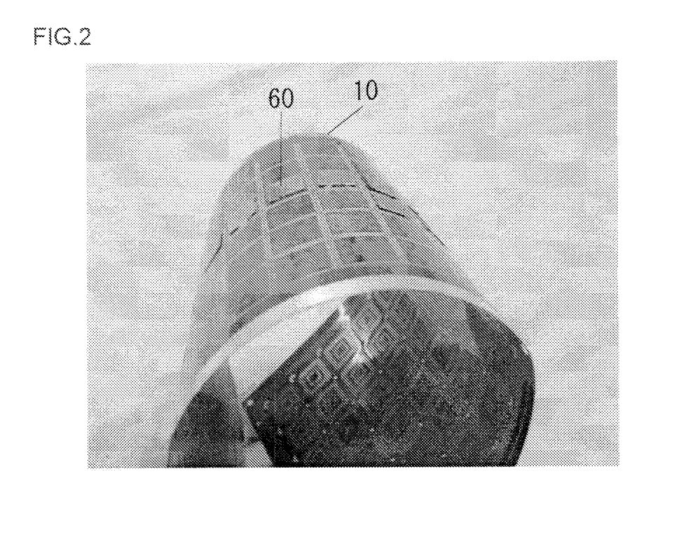

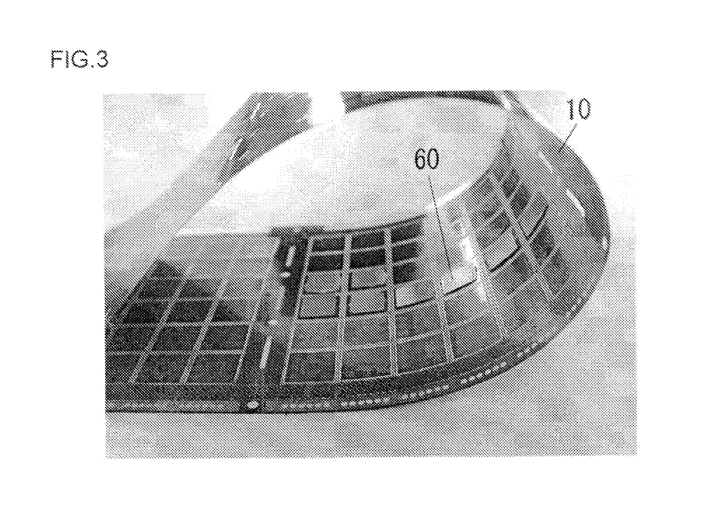

FIG. 2 and FIG. 3 are photos showing the respective states of circuit elements 60 mounted on a flexible substrate 10, which has been produced using a BT resin of 60 μm thickness as the insulating resin. As shown in these figures, the flexible substrate 10 is flexible enough to allow a 180-degree bending, and the flexible substrate 10 can solely provide both the movable and fixed parts of a circuit board.

The circuit elements 60 may be mounted on the peripheral side of a bent substrate as shown in FIG. 2 or on the inside thereof as shown in FIG. 3, which demonstrates that the flexible substrate 10 is subject to fewer limitations on where the circuit elements 60 are to be mounted thereon.

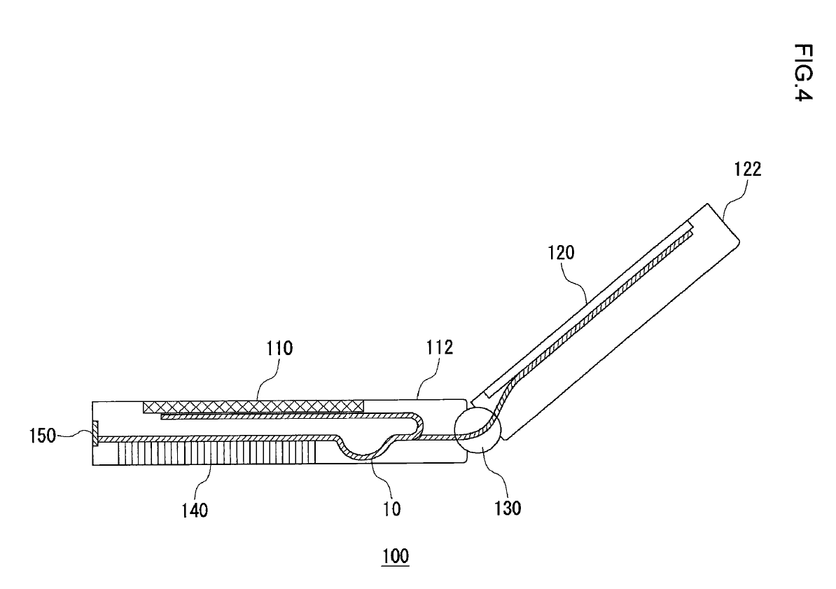

FIG. 4 is a sectional view showing a case in which a flexible substrate 10 is used as a circuit board for a mobile phone 100. The mobile phone 100 is a foldable mobile phone with a hinge 130 connecting a casing 112 which includes a controller 110 capable of processing signals inputted through buttons or the like and a casing 122 which includes a display unit 120 comprised of a liquid crystal display or the like. The casing 112 holds a secondary battery 140 as the power source. One end of the flexible substrate 10 is electrically connected to an external connection terminal 150. The flexible substrate 10, which has the circuit elements (not shown) mounted thereon, is held in the casing 112 in a folded-back state. At the folded-back point within the casing 112, the flexible substrate 10 branches off, and one branch is electrically connected to the controller 110 and the other branch is electrically connected to the display unit 120 in the casing 122 through the hinge 130.

The flexible substrate 10 is pliable enough to be bent into the space created inside the casing 112, and this facility allows an effective use of the space within the casing 112, which contributes to a smaller size of the mobile phone 100. Also, even in a case of a movable part, such as a hinge 130, is involved, the flexible substrate 10, which possesses both flexibility and rigidity, can form a circuit board without using separate members by which to connect the movable part and the fixed part. This facility leads to a simplified structure for such an application.

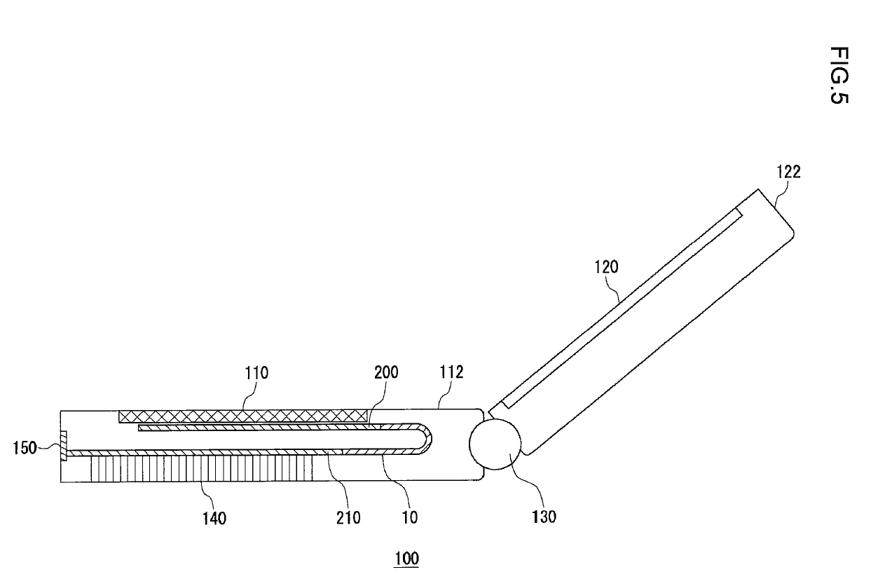

FIG. 5 to FIG. 7 show other examples in which a flexible substrate 10 is used as a circuit board for a mobile phone 100. In the examples shown in FIG. 5 to FIG. 7, the same components as those in the example of FIG. 4 are given the same reference numerals and the description thereof will be omitted as appropriate.

In the example shown in FIG. 5, provided are rigid substrates 200 and 210 which are supported by a controller 110 and a secondary battery 140, respectively. For example, epoxy resin may be used as the rigid substrates 200 and 210. A flexible substrate 10 is used to connect the rigid substrate 200 and the rigid substrate 210 in a folded-back state. Wiring layers (e.g., the first wiring layer 20 and the second wiring layer 50, see FIG. 1) provided on the flexible substrate 10 and wiring layers (not shown) in the rigid substrate 200 and the rigid substrate 210 are joined together by the soldering or wire bonding, for instance. In the example shown in FIG. 5, the flexible substrate 10 is used in a portion where once the flexible substrate 10 is folded back, it will be used in the same state. And the flexible substrate 10, which has both flexibility and rigidity, is suitably used for this application. If the rigid substrate 200 and 210 are used in parts which come in contact with the controller 110 and the secondary battery 140, respectively, the durability and the damage resistance can be improved.

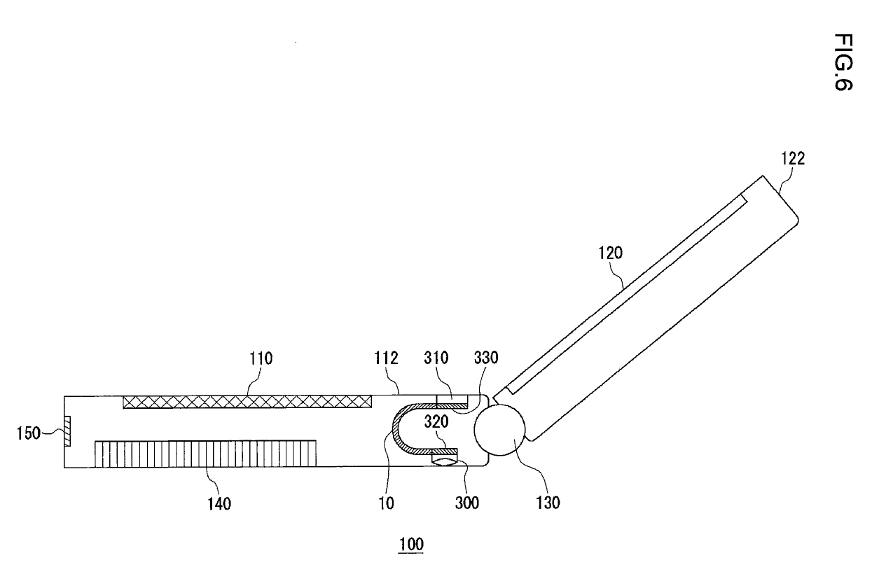

In the example shown in FIG. 6, an image signal processing unit 310 is provided which includes a camera unit 300 that houses an image-pickup lens, a CCD and the like and a processor that processes an image signal acquired by the camera unit 300. On the backsides of the camera unit 300 and the image signal processing unit 310, rigid substrates 320 and 330 are provided as their respective circuit boards. A flexible substrate 10 is used as a substrate that connects the rigid substrates 320 and 330 in a folded-back state. In the example shown in FIG. 6, the flexible substrate 10 is used in a portion where once the flexible substrate 10 is folded back, it will be used in the same state. And the flexible substrate 10, which has both flexibility and rigidity, is suitably used for this application. If the rigid substrates 320 and 330 are used in parts which come in contact with the camera unit 300 and the image signal processing unit 310, respectively, the durability and the damage resistance can be improved.

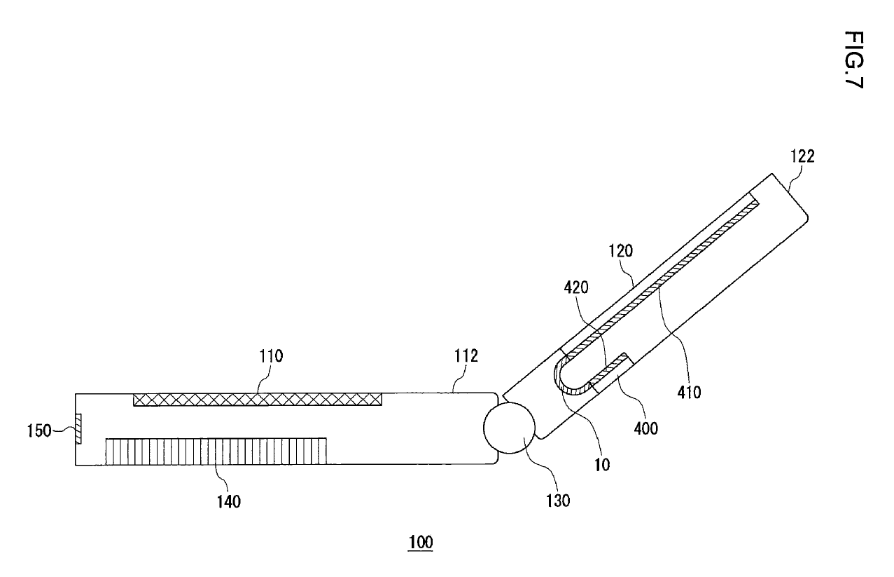

In the example shown in FIG. 7, a driver unit 400, which drives a liquid crystal display used as a display unit 120, is provided on opposite side of the display unit 120 in a casing 122. On the backsides of the display unit 120 and the driver unit 400, rigid substrates 410 and 420 are provided as their respective circuit boards. A flexible substrate 10 is used as a substrate that connects the rigid substrates 410 and 420 in a folded-back state. In the example shown in FIG. 7, the flexible substrate 10 is used in a portion where the flexible substrate 10 is folded back once, it will be used in the same state. And the flexible substrate 10, which has both flexibility and rigidity, is suitably used for this application. If the rigid substrates 410 and 420 are used in parts which come in contact with the display unit 120 and the driver unit 400, respectively, the durability and the damage resistance can be improved.

The present invention is not limited to the above-described embodiments only, and it is understood by those skilled in the art that various modifications such as changes in design may be made based on their knowledge and the embodiments added with such modifications are also within the scope of the present invention.

For example, a wiring layer, which is provided on each side of the insulating resin layer in the embodiment described above, may be provided on one side thereof only. Also, the insulating resin layer, which has both heat resistance and moisture resistance, is less prone to deformation due to expansion. Using this characteristic, multiple wiring layers can be formed in a stack with a plurality of insulating resin layers held in between so long as such a stack structure does not lose the flexibility.

Also, in the glass cloth 40 illustrated in FIG. 1, individual glass fibers are independently interwoven with one another, but the application covered herein is not limited thereto. For example, the glass cloth 40 may be formed by interweaving bundles of a plurality of glass fibers.

What is claimed:

1. A flexible substrate, comprising:
an insulating resin layer which contains a high elastic modulus and heat resistance;
glass fibers embedded in said insulating resin layer; and
a wiring layer provided on at least one surface of said insulating resin layer,
wherein said insulating layer is so thinned as to be flexible.

2. A flexible substrate according to claim 1, wherein said insulating resin layer further contains moisture resistance.

3. A flexible substrate according to claim 1, wherein said insulating resin layer further contains rigidity.

4. A flexible substrate according to claim 1, wherein at least part of said glass fibers is exposed on an end face of said insulating resin layer.
